(19) United States
(12) Patent Application Publication
(10) Pub. No.: US 2026/0082606 A1
(43) Pub. Date: Mar. 19, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Tomoko MATSUDAI, Shibuya Tokyo (JP); Kentaro ICHINOSEKI, Higashimurayama Tokyo (JP); Yusuke KOBAYASHI, Yokohama Kanagawa (JP); Takato YAMAMOTO, Kawasaki Kanagawa (JP)

(21) Appl. No.: 19/069,132

(22) Filed: Mar. 3, 2025

(30) Foreign Application Priority Data
Sep. 17, 2024 (JP) 2024-160302

(51) Int. Cl. H10D 12/00; H03K 17/567

(52) U.S. Cl. CPC H10D 12/481; H03K 17/567

(57) ABSTRACT

A semiconductor device according to an embodiment includes a first electrode and a second electrode disposed with a gap left from each other in a first direction. The semiconductor device includes a plurality of control electrodes disposed with gaps left therebetween in a second direction. The semiconductor device includes connection electrodes electrically connected to a first electrode. The semiconductor device includes a first semiconductor layer of a first conductivity type electrically connected to the first electrode. The semiconductor device includes a second semiconductor layer of the first conductivity type insulated from the first electrode. Each of a plurality of regions sandwiched between the control electrodes disposed to be adjacent to each other is either a channel region where the first semiconductor layer is disposed or a floating region where the second semiconductor layer is disposed.

### CROSS-REFERENCE TO RELATED APPLICATION

This application is based upon and claims the benefit of priority from Japanese Patent Application No. 2024-160302, filed on Sep. 17, 2024, the entire contents of which are incorporated herein by reference.

### FIELD

Embodiments described herein relate generally to a semiconductor device.

### BACKGROUND

As a semiconductor device, a bipolar device such as an IGBT, for example, is known. As compared with a unipolar device, the bipolar device can increase a carrier density in a base layer in an ON state (conductive state). Thus, it is easy to reduce an electrical resistance in the base layer and to thereby reduce a conduction loss in the ON state. However, it takes time for the bipolar device to discharge carriers accumulated in the base layer when it is turned off, and it is thus difficult to reduce a turn-off loss.

### BRIEF DESCRIPTION OF THE DRAWINGS

FIG. 1 is a schematic sectional view illustrating a semiconductor device according to a first embodiment.

FIG. 2 is a schematic view illustrating the semiconductor device according to the first embodiment.

FIG. 3 is a timing chart illustrating a control signal, a first voltage, and a second voltage of the semiconductor device according to the first embodiment.

FIG. 4 is a schematic front view illustrating a carrier behavior in a first period of the semiconductor device according to the first embodiment.

FIG. 5 is a schematic sectional view illustrating a carrier behavior in a second period of the semiconductor device according to the first embodiment.

FIG. 6 is a schematic sectional view illustrating a carrier behavior in a second period of a semiconductor device according to a comparative example.

FIG. 7 is a schematic sectional view illustrating a carrier behavior in a third period of the semiconductor device according to the first embodiment.

FIG. 8 is a schematic sectional view illustrating a semiconductor device according to a second embodiment.

FIG. 9 is a schematic sectional view illustrating a carrier behavior in a second period of the semiconductor device according to the second embodiment.

FIG. 10 is a schematic sectional view illustrating a semiconductor device according to a third embodiment.

FIG. 11 is a schematic sectional view illustrating a carrier behavior in a second period of the semiconductor device according to the third embodiment.

### DETAILED DESCRIPTION

A semiconductor device according to an embodiment includes a first electrode and a second electrode disposed with a gap left from each other in a first direction. The semiconductor device includes a plurality of control electrodes disposed between the first electrode and the second electrode and disposed with gaps left along a second direction that intersects the first direction. The semiconductor device includes connection electrodes electrically connected to a first electrode. The semiconductor device includes a first semiconductor layer of a first conductivity type electrically connected to the first electrode. The semiconductor device includes a second semiconductor layer of the first conductivity type electrically insulated from the first electrode. The semiconductor device includes a third semiconductor layer of a second conductivity type disposed between the second electrode and each of the first semiconductor layer and the second semiconductor layer. The semiconductor device includes a fourth semiconductor layer of the first conductivity type disposed between the second electrode and the third semiconductor layer. Each of the first semiconductor layer, the second semiconductor layer, the third semiconductor layer, and the fourth semiconductor layer is disposed between the first electrode and the second electrode. Each of a plurality of regions sandwiched between the control electrodes disposed to be adjacent to each other in the second direction is either a channel region where the first semiconductor layer is disposed or a floating region where the second semiconductor layer is disposed. The plurality of control electrodes includes a plurality of first control electrodes to which a first voltage is applied and a plurality of second control electrodes to which a second voltage is applied. The floating region includes a first floating region where at least one of the control electrodes sandwiching the floating region is the second control electrode. The connection electrodes are disposed in the first floating region.

Hereinafter, a semiconductor device according to an embodiment will be described with reference to the drawings.

A first direction D1 appropriately illustrated in each drawing is a direction that is parallel to a thickness direction of the semiconductor device. A side (+D1 side) that the arrow of the first direction D1 faces is an upper side of the semiconductor device. A side (−D1 side) opposite to the side that the arrow of the first direction D1 faces is a lower side of the semiconductor device. In the following description, the upper side of the semiconductor device will be simply referred to as an “upper side”, and the lower side of the semiconductor device will be simply referred to as a “lower side”. Note that each of the “upper side” and the “lower side” is not a term indicating a relationship with a gravity direction.

A second direction D2 appropriately indicated in each drawing is a direction intersecting the first direction D1. In the present embodiment, the second direction D2 perpendicularly intersects the first direction D1. The second direction D2 may not perpendicularly intersect the first direction D1. A side (+D2 side) that the arrow of the second direction D2 faces is a right side of the semiconductor device. A side (−D2 side) opposite to the side that the arrow of the second direction D2 faces is a left side of the semiconductor device. In the following description, the right side of the semiconductor device will be simply referred to as a “right side”, and the left side of the semiconductor device will be simply referred to as a “left side”.

A third direction D3 appropriately indicated in each drawing is a direction perpendicularly intersecting each of the first direction D1 and the second direction D2. Note that each of the “upper side”, the “lower side”, the “right side”, and the “left side” is just a name to explain a disposition relationship or the like of respective components constituting the semiconductor device, and an actual disposition relationship or the like may be a disposition relationship or the like other than the disposition relationship or the like indicated by these names.

In the specification, terms such as “perpendicularly intersecting”, “same”, “similar”, and “parallel”, length values, and the like, for example, that specify the shape of each component constituting the semiconductor device and a degree of a relative disposition relationship of each component are not limited to their strict meanings and are to be interpreted as including ranges in which similar functions can be expected and ranges of design tolerance.

In the specification, designations of N⁺, N, N⁻, P⁺, and P represent how relatively high the carrier concentration of each conductive type is. N⁺ indicates that the carrier concentration of the N type is relatively higher than that of N, and N-indicates that the carrier concentration of the N type is relatively lower than that of N. P⁺ indicates that the carrier concentration of the P type is relatively higher than that of P. Also, the P type is a first conductivity type while the N type is a second conductivity type in the specification.

In the specification, a carrier concentration in a semiconductor region can be measured using a cyclic voltammetry (CV) instrument, for example. Also, the carrier concentration in the semiconductor region may be calculated from an impurity concentration measured using secondary ion mass spectrometry (SIMS), for example. How relatively large and small the carrier concentrations in two semiconductor regions are can be determined using scanning capacitance microscopy (SCM), for example. Also, a distribution and absolute values of carrier concentrations can be measured using spreading resistance analysis (SRA), for example.

### First Embodiment

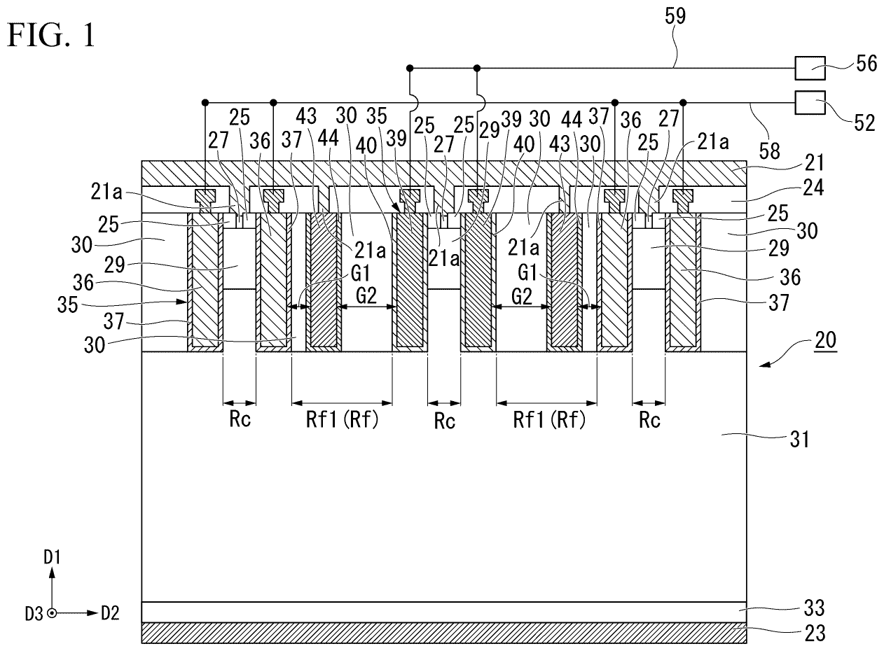

FIG. 1 is a schematic sectional view illustrating a semiconductor device 20 according to the present embodiment. The semiconductor device 20 according to the present embodiment is a bipolar device such as an insulated gate bipolar transistor (IGBT). The semiconductor device 20 is used as a power semiconductor device. The semiconductor device 20 can be used as a switching device. As illustrated in FIG. 1, the semiconductor device 20 includes an emitter electrode 21, a collector electrode 23, an insulating layer 24, N⁺-type emitter layers 25, P⁺-type contact layers 27, P-type base layers 29, P-type floating layers 30, an N-type base layer 31, a P-type collector layer 33, control electrodes 35, first insulating films 37, second insulating films 40, connection electrodes 43, and a third insulating film 44.

The emitter electrode 21 spreads in a direction perpendicularly intersecting the first direction D1. In the present embodiment, the emitter electrode 21 is a first electrode. In other words, the semiconductor device 20 includes the first electrode. The emitter electrode 21 may contain metal showing a Schottky characteristic with respect to an N-type semiconductor. The emitter electrode 21 is constituted by, for example, at least one metal material selected from aluminum, copper, tantalum, silver, molybdenum, tungsten, cobalt, chromium, ruthenium, gold, palladium, nickel, platinum, and the like.

The collector electrode 23 spreads in the direction perpendicularly intersecting the first direction D1. The collector electrode 23 is disposed with a gap left from the emitter electrode 21 in the first direction D1. The collector electrode 23 is disposed further downward (−D1 side) than the emitter electrode 21. In the present embodiment, the collector electrode 23 is a second electrode. In other words, the semiconductor device 20 includes the second electrode. The collector electrode 23 is made of metal.

The insulating layer 24 is disposed between the emitter electrode 21 and the collector electrode 23. The insulating layer 24 spreads in the direction perpendicularly intersecting the first direction D1. A surface of the insulating layer 24 facing upward (+D1 side) is in contact with a surface of the emitter electrode 21 facing downward (−D1 side). The insulating layer 24 has an insulating property. It is possible to use, for example, silicon oxide as a material constituting the insulating layer 24. The insulating layer 24 is provided with a plurality of holes penetrating through the insulating layer 24 in the first direction D1. Each hole accommodates a projecting portion 21a which is a part of the emitter electrode 21 and projects downward.

The control electrodes 35 are electrodes that control an ON operation and an OFF operation of the semiconductor device 20. The control electrodes 35 are disposed between the emitter electrode 21, namely the first electrode, and the collector electrode 23, namely the second electrode. The control electrodes 35 extend in each of the first direction D1 and the third direction D3. An end portion of each control electrode 35 on the upper side (+D1 side) is in contact with a surface of the insulating layer 24 facing downward (−D1 side). The control electrodes 35 are constituted by a semiconductor material to which impurities are added. The semiconductor device 20 includes the plurality of control electrodes 35. The control electrodes 35 are disposed with gaps left along the second direction D2. The plurality of control electrodes 35 includes a plurality of first control electrodes 36 and a plurality of second control electrodes 39. A first voltage Vg1, which will be described later, is applied to each first control electrode 36. The first control electrodes 36 are disposed with gaps left in the second direction D2.

A second voltage Vg2, which will be described later, is applied to each second control electrode 39. In the present embodiment, discharge of holes accumulated in the N⁻-type base layer 31 is controlled by controlling the second voltage Vg2. In the present embodiment, each second control electrode 39 is disposed between a pair of two first control electrodes 36. In the present embodiment, each first control electrode 36 and each second control electrode 39 are constituted by the same material.

Note that although FIG. 1 illustrates an example in which the structure of the first control electrodes 36 and the structure of the second control electrodes 39 are the same, the structure of the first control electrodes 36 and the structure of the second control electrodes 39 may be different from each other. For example, the dimension of the first control electrodes 36 in the first direction D1 and the dimension thereof in the second direction D2 may be different from the dimension of the second control electrodes 39 in the first direction D1 and the dimension thereof in the second direction D2, respectively. Moreover, the number of first control electrodes 36 and the number of second control electrodes 39 are not limited to the numbers illustrated in FIG. 1.

In the present embodiment, each of a plurality of regions each sandwiched by the control electrodes 35 disposed to be adjacent to each other in the second direction D2 is a region which is either a channel region Rc or a floating region Rf. In the present embodiment, the channel region Rc is a region between the first control electrodes 36 disposed to be adjacent to each other and a region between the second control electrodes 39 disposed to be adjacent to each other. Each channel region Rc is a region where the N⁺-type emitter layer 25, the P⁺-type contact layer 27, the P-type base layer 29, and a part of the N⁻-type base layer 31 are disposed. In the present embodiment, the floating regions Rf are regions other than the channel regions Rc from among the plurality of regions sandwiched between the control electrodes 35 disposed to be adjacent to each other in the second direction D2. Each floating region Rf is a region where the P-type floating layer 30, the connection electrode 43, and a third insulating film 44 are disposed. In the present embodiment, each floating region Rf includes a first floating region Rf1. In the present embodiment, each floating region Rf includes only the first floating region Rf1.

Each first floating region Rf1 is a region where at least one of the control electrodes 35 sandwiching the floating region Rf is the second control electrode 39. In the present embodiment, the first floating region Rf1 is sandwiched between one first control electrode 36 and one second control electrode 39. In the present embodiment, the channel regions Rc and the first floating regions Rf1 are alternately provided along the second direction D2.

The first insulating films 37 are insulating films that cover the first control electrodes 36. End portion of the first insulating films 37 on the upper side (D1 side) are in contact with a surface of the insulating layer 24 on the lower side (−D1 side). It is possible to use, for example, silicon oxide as a material constituting the first insulating films 37. The semiconductor device 20 includes a plurality of first insulating films 37. The first insulating films 37 cover the mutually different first control electrodes 36.

The second insulating films 40 are insulating films that cover the second control electrodes 39. End portions of the second insulating films 40 on the upper side (D1 side) are in contact with the surface of the insulating layer 24 facing downward (−D1 side). It is possible to use silicon oxide, for example, as a material constituting the second insulating films 40. The semiconductor device 20 includes a plurality of second insulating films 40. The second insulating films 40 cover the mutually different second control electrodes 39.

The N⁺-type emitter layers 25 are disposed in the channel regions Rc. The N⁺-type emitter layers 25 are disposed between the first control electrodes 36 disposed to be adjacent to each other in the second direction D2 or between the second control electrodes 39 disposed to be adjacent to each other in the second direction D2. End portions of the N⁺-type emitter layers 25 on the upper side (+D1 side) are in contact with the insulating layer 24 and projecting portions 21a of the emitter electrode 21. In this manner, the N⁺-type emitter layers 25 are electrically connected to the emitter electrode 21. End portions of the N⁺-type emitter layers 25 on the lower side (−D1 side) are located further upward than the end portions of the control electrodes 35 on the lower side. The N-type carrier concentration in the N⁺-type emitter layers 25 is, for example, equal to or greater than 1×10¹⁹ [cm⁻³] and equal to or less than 1×10²⁰ [cm⁻³]. In the present embodiment, the semiconductor device 20 includes the plurality of N⁺-type emitter layers 25. The N⁺-type emitter layer 25 is disposed in each channel region Rc. The N⁺-type emitter layer 25 is in contact with either the first insulating film 37 or the second insulating film 40 in the second direction D2 in each channel region Rc. In this manner, N⁺-type emitter layers 25 are insulated from the control electrodes 35.

The P⁺-type contact layers 27 are disposed in the channel regions Rc. End portions of the P⁺-type contact layers 27 on the upper side (+D1 side) are in contact with the projecting portions 21a of the emitter electrode 21. In this manner, the P⁺-type contact layers 27 are electrically connected to the emitter electrode 21. End portions of the P⁺-type contact layers 27 on the lower side (−D1 side) are located further upward than the end portions of the control electrodes 35 on the lower side. The P-type carrier concentration in the P⁺-type contact layers 27 is, for example, equal to or greater than 1×10¹⁹ [cm⁻³] and equal to or less than 1×10²⁰ [cm⁻³]. In the present embodiment, the semiconductor device 20 includes the plurality of P⁺-type contact layers 27. The P⁺-type contact layers 27 are disposed in mutually different channel regions Rc. The P⁺-type contact layers 27 are in contact with the N⁺-type emitter layers 25.

The P-type base layers 29 are semiconductor layers of the P type, that is, the first conductivity type. In the present embodiment, the P-type base layers 29 are first semiconductor layers. The P-type base layers 29 are disposed between the emitter electrode 21 and the collector electrode 23. The P-type base layers 29 are disposed in the channel regions Rc. In other words, the P-type base layers 29, that is, the first semiconductor layers are disposed in the channel regions Rc. The P-type base layers 29 are disposed between the first control electrodes 36 disposed to be adjacent to each other in the second direction D2 or between the second control electrodes 39 disposed to be adjacent to each other in the second direction D2. The P-type base layers 29 are disposed between the side of the N⁺-type emitter layers 25 and the P⁺-type contact layers 27 and the collector electrode 23. End portions of the P-type base layers 29 on the upper side (+D1 side) are in contact with each of the N⁺-type emitter layers 25 and the P⁺-type contact layers 27. In this manner, the P-type base layers 29 are electrically connected to the emitter electrode 21, that is, the first electrode via the N⁺-type emitter layers 25 and the P⁺-type contact layers 27. End portions of the P-type base layers 29 on the lower side (−D1 side) are located further upward than the end portions of the control electrodes 35 on the lower side. The P-type carrier concentration in the P-type base layers 29 is, for example, about 1×10¹⁷ [cm⁻³]. In the present embodiment, the semiconductor 20 includes the plurality of P-type base layers 29. The carrier concentration of each P-type base layer 29 is lower than the carrier concentration of the P⁺-type contact layers 27. The P-type base layers 29 are disposed in mutually different channel regions Rc. Each P-type base layer 29 is in contact with either the first insulating film 37 or the second insulating film 40 in the second direction D2. In this manner, the P-type base layers 29 are insulated from the control electrodes 35.

The P-type floating layers 30 are semiconductor layers of the P type, that is, the first conductivity type. In the present embodiment, the P-type floating layers 30 are second semiconductor layers. The P-type floating layers 30 are disposed between the emitter electrode 21 and the collector electrode 23. The P-type floating layers 30 are disposed in the first floating regions Rf1. In other words, the P-type floating layers 30, that is, the second semiconductor layers are disposed in the floating regions Rf. The P-type floating layers 30 are disposed between the insulating layer 24 and the collector electrode 23. End portions of the P-type floating layers 30 on the upper side (+D1 side) are in contact with the insulating layer 24. In this manner, the P-type floating layers 30 are electrically insulated from the emitter electrode 21, that is, the first electrode. In the first direction D1, the positions of the end portions of the P-type floating layers 30 on the lower side (−D1 side) and the position of the end portions of the control electrodes 35 on the lower side are substantially the same positions. The end portions of the P-type floating layers 30 on the lower side may be located further upward or further downward than the end portions of the control electrodes 35 on the lower side. In a case where end portions of the P-type floating layers 30 on the lower side are located further downward than the end portions of the control electrodes 35 on the lower side, it is possible to curb concentration of an electric field at corner portions of the control electrodes 35 on the lower side when a voltage is applied to the control electrodes 35. In this manner, it is possible to curb avalanche breakdown which is caused by the control electrodes 35 and thereby to enhance reliability of operations of the semiconductor device 20 as well. The P-type carrier concentration in the P-type floating layers 30 is, for example, about 1×10¹⁷ [cm⁻³]. In the present embodiment, the semiconductor device 20 includes the plurality of P-type floating layer 30. The P-type floating layers 30 are disposed in the mutually different first floating regions Rf1. Each P-type floating layer 30 is in contact with at least either the first insulating film 37 or the second insulating film 40 in the second direction D2. In this manner, the P-type floating layers 30 are insulated from the control electrodes 35.

The N⁻-type base layer 31 is a semiconductor layer of the N type, that is, the second conductivity type. In the present embodiment, the N⁻-type base layer 31 is a third semiconductor layer. The N⁻-type base layer 31 is disposed between the emitter electrode 21 and the collector electrode 23. The N⁻-type base layer 31 is disposed between the connector electrode 23 and each of the P-type base layers 29, the P-type floating layers 30, and the control electrodes 35. In other words, the N⁻-type base layer 31 is disposed between the second electrode and each of the first semiconductor layers and the second semiconductor layers. Parts of the N⁻-type base layer 31 project into the channel regions Rc and are in contact with the P-type base layers 29. The other parts of the N⁻-type base layer 31 are in contact with the P-type floating layers 30. In this manner, the N-type base layer 31 is in contact with each of the P-type base layers 29 and the P-type floating layers 30. The N⁻-type base layer 31 is in contact with each of the first insulating films 37 and the second insulating films 40. In this manner, the N⁻-type base layer 31 is insulated from the control electrodes 35. The N-type carrier concentration in the N⁻-type base layer 31 is, for example, about 1×10¹³ [cm⁻³]. The N-type carrier concentration in the N⁻-type base layer 31 is lower than the carrier concentration in the N⁺-type emitter layers 25. The N-type carrier concentration in the N-type base layer 31 can be set to an arbitrary carrier concentration depending on a pressure resistance design or the like of the semiconductor device 20.

The P-type collector layer 33 is a semiconductor layer of the P type, that is, the first conductivity type. In the present embodiment, the P-type collector layer 33 is a fourth semiconductor layer. The carrier concentration in the P-type collector layer 33 is higher than the carrier concentration in the P-type base layers 29. The P-type collector layer 33 is disposed between the emitter electrode 21 and the collector electrode 23. The P-type collector layer 33 is disposed between the collector electrode 23, that is, the second electrode and the N⁻-type base layer 31, that is, the third semiconductor layer. The P-type collector layer 33 is in contact with each of the collector electrode 23 and the N⁻-type base layer 31.

The connection electrodes 43 are disposed between the insulating layers 24 and the N⁻-type base layer 31. The connection electrodes 43 extend in each of the first direction D1 and the third direction D3. End portions of the connection electrodes 43 on the upper side (+D1 side) are in contact with the surfaces of the insulating layer 24 facing downward (−D1 side) and the projecting portions 21a of the emitter electrode 21. In this manner, the connection electrodes 43 are electrically connected to the emitter electrode 21, that is, the first electrode. The connection electrodes 43 are constituted by a semiconductor material to which impurities are added. The semiconductor device 20 includes the plurality of connection electrodes 43. The connection electrodes 43 are disposed with gaps left from each other along the second direction D2. The connection electrodes 43 are disposed in the mutually different first floating regions Rf1. In other words, the connection electrodes 43 are disposed in the first floating regions Rf1. As described above, each first floating region Rf1 is sandwiched between one first control electrode 36 and one second control electrode 39 in the present embodiment. Therefore, each connection electrode 43 is sandwiched between one first control electrode 36 and one second control electrode 39. In the present embodiment, a gap G2 between the connection electrodes 43 and the second control electrodes 39 is larger than a gap G1 between the connection electrodes 43 and the first control electrodes 36. Note that the gap G2 between the connection electrodes 43 and the second control electrodes 39 may be smaller than the gap G1 between the connection electrodes 43 and the first control electrodes 36 or may have the same dimension as that of the gap G1 between the connection electrodes 43 and the first control electrodes 36.

The third insulating films 44 are insulating films that cover the connection electrodes 43. End portions of the third insulating films 44 on the upper side (D1 side) are in contact with the surface of the insulating layer 24 on the lower side (−D1 side). It is possible to use silicon oxide, for example, as a material constituting the third insulating films 44. The semiconductor device 20 includes the plurality of third insulating films 44. The third insulating films 44 cover the mutually different connection electrodes 43. The third insulating films 44 are in contact with the P-type floating layers 30 and the N⁻-type base layer 31. In this manner, the connection electrodes 43 are insulated from each of the P-type floating layers 30 and the N⁻-type base layer 31.

Next, an electrical connection relationship between the first control electrodes 36 and the second control electrodes 39 will be described. In the present embodiment, each first control electrode 36 is electrically connected to a first gate pad 52 via a wiring 58. Each second electrode 39 is electrically connected to a second gate pad 56 via a wiring 59. A first voltage Vg1 which is a first gate-emitter voltage is applied to the first gate pad 52. In this manner, the first voltage Vg1 is applied to each first control electrode 36. A second voltage Vg2 which is a second gate-emitter voltage is applied to the second gate pad 56. In this manner, the second voltage Vg2 is applied to each second control electrode 39. Therefore, it is possible to apply mutually different voltages to the first control electrodes 36 and the second control electrodes 39.

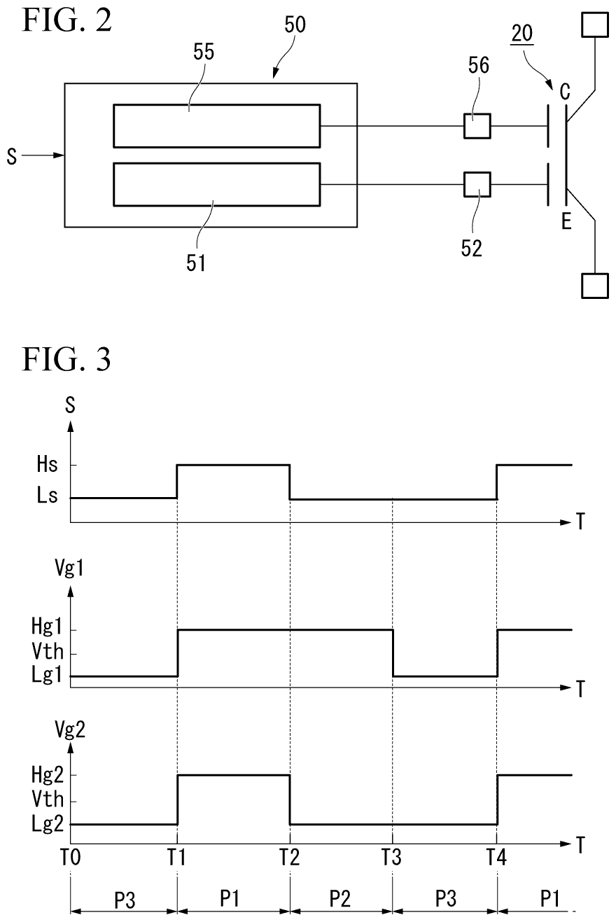

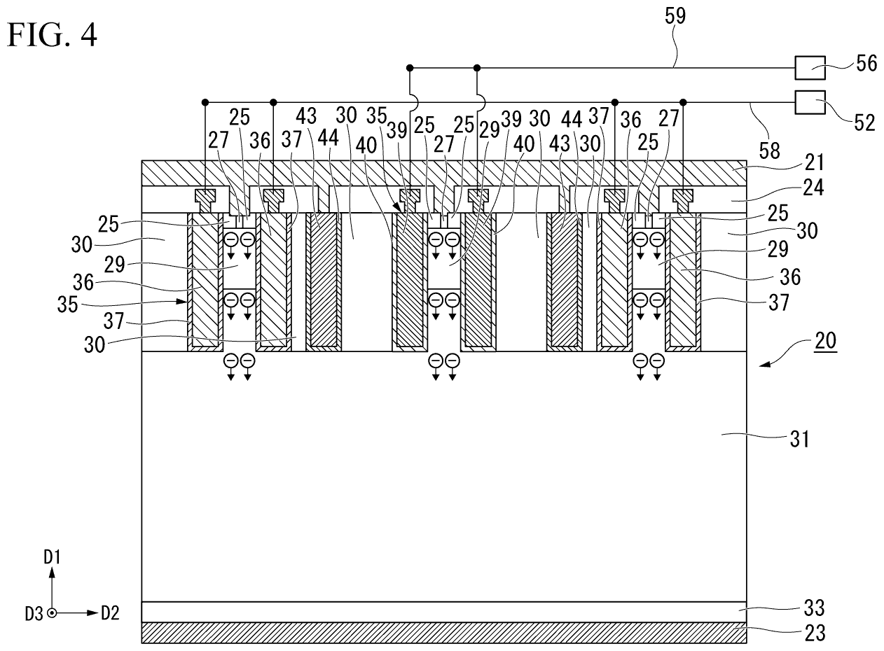

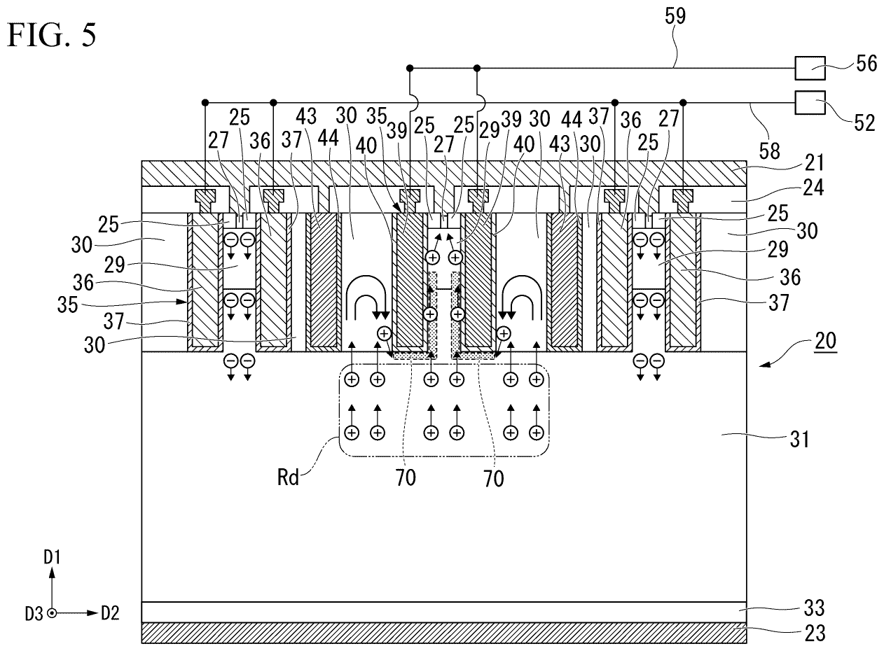

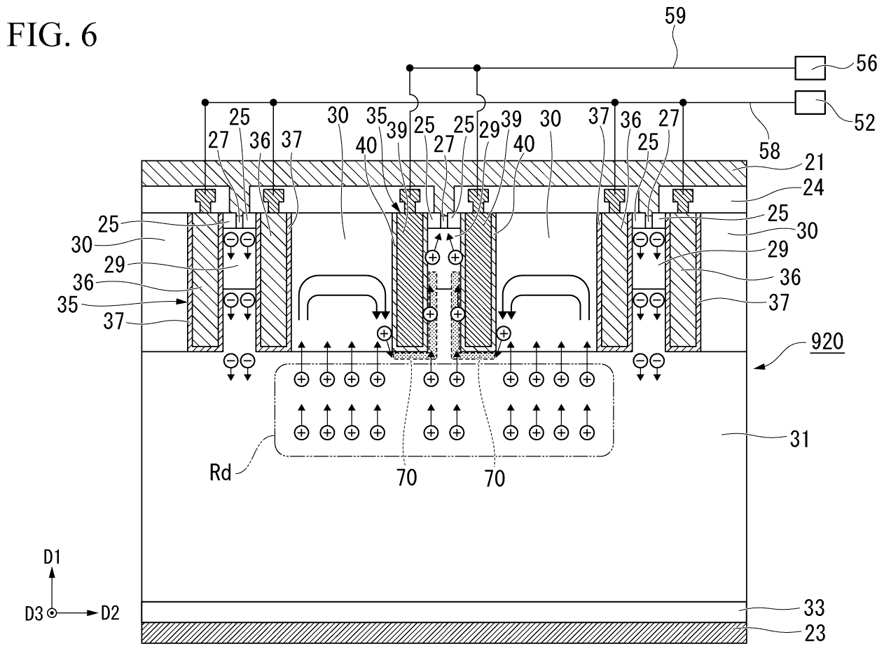

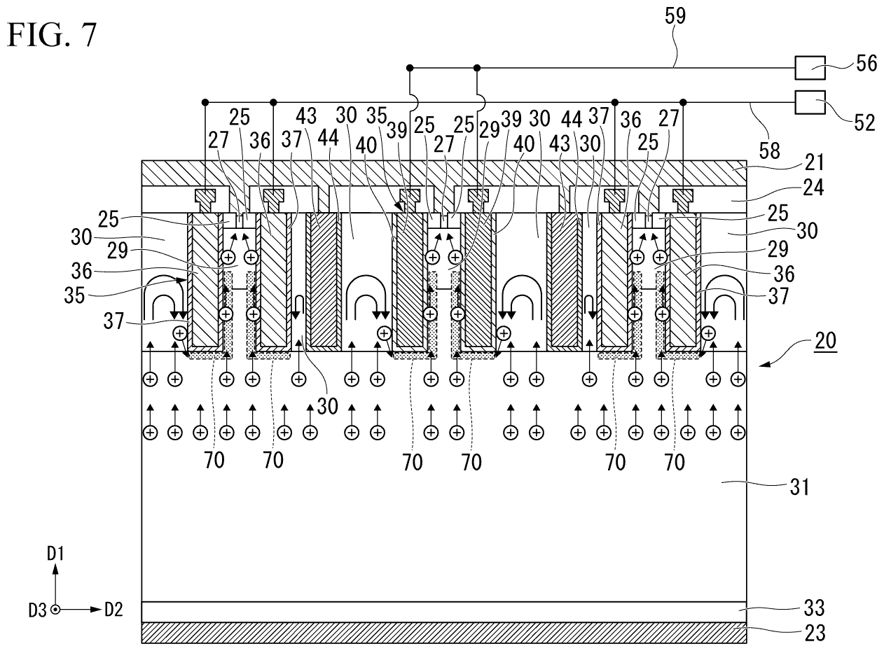

FIG. 2 is a schematic view illustrating the semiconductor device 20 according to the present embodiment. FIG. 3 is a timing chart illustrating a control signal, the first voltage Vg1, and the second voltage Vg2 of the semiconductor device 20 according to the present embodiment. FIG. 4 is a schematic sectional view illustrating a carrier behavior in a first period of time P1 of the semiconductor device 20 according to the present embodiment. FIG. 5 is a schematic sectional view illustrating a carrier behavior in a second period of time P2 of the semiconductor device 20 according to the present embodiment. FIG. 6 is a schematic sectional view illustrating a carrier behavior in the second period of time P2 of a semiconductor device 920 according to a comparative example. FIG. 7 is a schematic sectional view illustrating a carrier behavior in a third period of time P3 of the semiconductor device 20 according to the present embodiment. As illustrated in FIG. 2, the semiconductor device 20 includes a voltage control circuit 50.

The voltage control circuit 50 can control the first voltage Vg1 to be applied to the first gate pad 52 and the second voltage Vg2 to be applied to the second gate pad 56 at mutually different timings. The voltage control circuit 50 includes a first control circuit 51 and a second control circuit 55.

The first control circuit 51 applies the first voltage Vg1 to the first control electrodes 36 via the first gate pad 52 on the basis of a control signal S input from the outside. The second control circuit 55 applies the second voltage Vg2 to the second control electrodes 39 via the second gate pad 56 on the basis of the control signal S input from the outside. As illustrated in FIG. 3, the control signal S is a binary signal constituted by Hs and Ls. Note that mutually different control signals may be input to the first control circuit 51 and the second control circuit 55.

The first control circuit 51 applies either a first high voltage Hg1 or a first low voltage Lg1 as the first voltage Vg1 to each first control electrode 36 on the basis of the control signal S. The first high voltage Hg1 is higher than a threshold voltage Vth at which a channel is formed in the semiconductor device 20. The first low voltage Lg1 is lower than the threshold voltage Vth. Therefore, once the first high voltage Hg1 is applied to the first control electrodes 36, the semiconductor device 20 is brought into an ON state (conductive state). At this time, a current flows from the collector electrode 23 to the emitter electrode 21 via the channel regions Rc provided between the first control electrodes 36 disposed to be adjacent to each other. Once the first low voltage Lg1 is applied to the first control electrodes 36, the semiconductor device 20 is brought into an OFF state.

The second control circuit 55 applies either a second high voltage Hg2 or a second low voltage Lg2 as the second voltage Vg2 to each second control electrode 39 on the basis of the control signal S. The second high voltage Hg2 is higher than the threshold voltage Vth at which a channel is formed in the semiconductor device 20. The second low voltage Lg2 is lower than the threshold voltage Vth. Therefore, once the second high voltage Hg2 is applied to the second control electrodes 39, the semiconductor device 20 is brought into the ON state, and a current flows from the collector electrode 23 to the emitter electrode 21 via the channel regions Rc provided between the second control electrodes 39 disposed to be adjacent to each other. Once the second low voltage Lg2 is applied to the second control electrodes 39, the semiconductor device 20 is brought into the OFF state.

Next, a switching timing of each of the first voltage Vg1 and the second voltage Vg2 will be described. Each of T0, T1, T2, T3, and T4 illustrated in FIG. 3 indicates a clock time, and the clock time passes in this order. In the present embodiment, the semiconductor device 20 is triggered by the switching of the control signal S from Ls to Hs and is brought into the ON state. Note that the relationship between the control signal S and the ON state of the semiconductor device 20 may be opposite to the above relationship. In other words, the semiconductor device 20 may be triggered by the switching of the control signal S from Ls to Hs and is brought into the OFF state.

The control signal S input to the voltage control circuit 50 from the clock time T0 to the clock time T1 is Ls. The first control circuit 51 outputs the first low voltage Lg1 as the first voltage Vg1. The second control circuit 55 outputs the second low voltage Lg2 as the second voltage Vg2. In this manner, the semiconductor device 20 is brought into the OFF state where the current does not flow from the collector electrode 23 to the emitter electrode 21.

The control signal S input to the voltage control circuit 50 at the clock time T1 is switched from Ls to Hs. At the clock time T1, the first control circuit 51 switches the first voltage Vg1 to the first high voltage Hg1. The second control circuit 55 switches the second voltage Vg2 to the second high voltage Hg2. In this manner, electrons move from the emitter electrode 21 to the collector electrode 23 via each channel region Rc as illustrated in FIG. 4 at the clock time T1. In this manner, the semiconductor device 20 is brought into the ON state where the current flows from the collector electrode 23 to the emitter electrode 21. In other words, the semiconductor device 20 is turned on and is switched from the OFF state to the ON state at the clock time T1.

As illustrated in FIG. 3, the control signal S input to the voltage control circuit 50 is Hs from the clock time T1 to the clock time T2 in the present embodiment. In the following description, the period of time from the clock time T1 to the clock time T2 will be referred to as a first period of time P1. In the first period of time P1, the semiconductor device 20 is in the ON state. As described above, the semiconductor device 20 according to the present embodiment is a bipolar device. Therefore, electrons and holes are injected to the N⁻-type base layer 31 in the ON state although illustration is omitted. In this manner, it is possible to increase the carrier concentration in the N⁻-type base layer 31 and to thereby reduce the electrical resistance of the N⁻-type base layer 31 in the ON state as compared with a unipolar device. Therefore, it is possible to reduce a conduction loss in the ON state as compared with the unipolar device according to the semiconductor device 20 of the present embodiment.

Note that the timing at which the first voltage Vg1 is switched to the first high voltage Hg1 and the timing at which the second voltage Vg2 is switched to the second high voltage Hg2 when the semiconductor device 20 is turned on may be the same or different from each other.

In the present embodiment, the control signal S input to the voltage control circuit 50 is switched from Hs to Ls at the clock time T2. At the clock time T2, the semiconductor device 20 experiences first turning-off. At the clock time T2, the first control circuit 51 maintains the first voltage Vg1 at the first high voltage Hg1. The second control circuit 55 switches the second voltage Vg2 to the second low voltage Lg2. In this manner, the state where the electrons move from the emitter electrode 21 to the collector electrode 23 via the channel regions Rc provided between the first control electrodes 36 disposed to be adjacent to each other is maintained as illustrated in FIG. 5 at the clock time T2. In this manner, the state where the current flows from the collector electrode 23 to the emitter electrode 21 is also maintained. On the other hand, the movement of the electrons from the emitter electrode 21 to the collector electrode 23 is stopped in the channel regions Rc provided between the second control electrodes 39 disposed to be adjacent to each other.

Also, the holes accumulated in the N⁻-type base layer 31 are discharged to the emitter electrode 21 via the channel regions Rc provided between the second control electrodes 39 disposed to be adjacent to each other. More specifically, the holes accumulated in a hole discharge region Rd which overlaps the part between the two connection electrodes 43 when seen in the first direction D1 in the N⁻-type base layer 31 are discharged to the emitter electrode 21. Some of the holes accumulated in the hole discharge region Rd are discharged to the emitter electrode 21 via carrier accumulation layers 70, the P-type base layers 29, and the like. Also, the other holes accumulated in the hole discharge region Rd move to the P-type floating layers 30 and are then discharged to the emitter electrode 21 via the carrier accumulation layers 70, the P-type base layers 29, and the like.

As illustrated in FIG. 3, the first turning-off is continued until the clock time T3 which is a clock time after a predetermined time elapses from the clock time T2 in the present embodiment. In the following description, the period of time from the clock time T2 to the clock time T3 will be referred to as a second period of time P2. As illustrated in FIG. 5, the semiconductor device 20 is in the ON state where the current flows from the collector electrode 23 to the emitter electrode 21 via the channel regions Rc provided between the first control electrodes 36 disposed to be adjacent to each other as described above in the second period of time P2. Also, since some of the holes accumulated in the hole discharge region Rd are discharged to the emitter electrode 21 as described above in the second period of time P2, it is possible to reduce the concentration of carriers accumulated in the N⁻-type base layer 31.

The semiconductor device 920 according to the comparative example illustrated in FIG. 6 does not include the connection electrodes 43. Therefore, the hole discharge region Rd of the semiconductor device 920 overlaps the part between the first control electrodes 36 sandwiching the second control electrodes 39 when seen in the first direction D1 in the N⁻-type base layer 31 in the second period of time P2. In this case, since a range of the hole discharge region Rd in the second direction D2 is large, the amount of carriers discharged to the emitter electrode 21 becomes excessively large in the second period of time P2. In this manner, the concentration of carriers accumulated in the N⁻-type base layer 31 becomes excessively low in the second period of time P2. Therefore, since the electrical resistance of the N⁻-type base layer 31 increases, a conduction loss in the second period of time P2 increases in the semiconductor device 920.

On the other hand, as illustrated in FIG. 5, the semiconductor device 20 according to the present embodiment includes the connection electrodes 43, and it is thus possible to reduce the range of the hole discharge region Rd in the second direction D2 as compared with the hole discharge region Rd of the semiconductor device 920 described above. This is because the parts of the P-type floating layers 30 sandwiched between the first control electrodes 36 and the connection electrodes 43 are not electrically connected to the P-type base layers 29 via the carrier accumulation layers 70 and thus do not contribute to the discharge of the holes. In this manner, it is possible to curb an excessive increase in the amount of carriers discharged to the emitter electrode 21 and to thereby curb an excessive decrease in concentration of carriers accumulated in the N⁻-type base layer 31. Therefore, it is possible to curb an excessive increase in electrical resistance of the N⁻-type base layer 31 and to thereby curb an increase in conductive loss in the second period of time P2.

Also, as illustrated in FIG. 1, the gap G2 between the connection electrodes 43 and the second control electrodes 39 is larger than the gap G1 between the connection electrodes 43 and the first control electrodes 36 in the present embodiment. It is thus easy to increase the range of the hole discharge region Rd in the second direction D2 illustrated in FIG. 5. Therefore, it is possible to suitably increase the amount of carriers discharged to the emitter electrode 21 in the second period of time P2. Therefore, it is possible to suitably reduce the concentration of carriers accumulated in the N⁻-type base layer 31. Although illustration is omitted, in a case where the gap G2 between the connection electrodes 43 and the second control electrodes 39 is smaller than the gap G1 between the connection electrodes 43 and the first control electrodes 36, it is possible to reduce the range of the hole discharge region Rd in the second direction D2. Therefore, it is possible to reduce the amount of carriers discharged to the emitter electrode 21 in the second period of time P2. It is thus possible to curb an excessive decrease in concentration of carriers accumulated in the N⁻-type base layer 31. In this manner, it is possible to curb an increase in electrical resistance of the N⁻-type base layer 31 and to suitably curb an increase in conductive loss in the second period of time P2. In other words, it is possible to adjust the carrier concentration in the N⁻-type base layer 31 in the second period of time P2 by appropriately adjusting the position of each connection electrode 43 in the second direction D2 in the present embodiment. In this manner, it is possible to curb an increase in turn-off loss in the third period of time P3 as will be described later while curbing an increase in conduction loss in the second period of time P2.

As illustrated in FIG. 3, the voltage control circuit 50 switches the first voltage Vg1 from the first high voltage Hg1 to the first low voltage Lg1 at the clock time T3. In other words, the voltage control circuit 50 switches the first voltage Vg1 after elapse of a predetermined time from the switching of the second voltage Vg2 at the clock time T2. Also, the voltage control circuit 50 maintains the second voltage Vg2 at the second low voltage Lg2. At the clock time T3, the semiconductor device 20 experiences second turning-off. In this manner, the semiconductor device 20 at the clock time T3 is in the OFF state where the current does not flow from the collector electrode 23 to the emitter electrode 21 as illustrated in FIG. 7.

At the clock time T3, the carrier accumulation layer 70 is formed at each of an interface between the first insulating films 37 and the N⁻-type base layer 31 and the interface between the second insulating films 40 and the N⁻-type base layer 31. The holes accumulated in the N⁻-type base layer 31 are discharged to the emitter electrode 21 via the carrier accumulation layers 70 and each channel region Rc.

As illustrated in FIG. 3, the second turning-off is continued until the clock time T4 which is a clock time after elapse of a predetermined time from the clock time T3. In the following description, the period from the clock time T3 to the clock time T4 will be referred to as a third period of time P3. In the third period of time P3, the semiconductor device 20 is in the OFF state. Also, in the third period of time P3, the holes accumulated in the N⁻-type base layer 31 are discharged to the emitter electrode 21. In the present embodiment, the carrier concentration in the N⁻-type base layer 31 is reduced by discharging some of the holes accumulated in the N⁻-type base layer 31 to the emitter electrode 21 in the second period of time P2 as described above. In this manner, it is possible to reduce the amount of holes discharged to the emitter electrode 21 in the third period of time P3 and to thereby shorten the time during which the carriers are discharged to the emitter electrode 21 in the third period of time P3. Therefore, it is possible to suitably reduce a turning-off loss in the third period of time P3.

Once the clock time T4 arrives, the control signal S is switched from Ls to Hs, and the semiconductor device 20 is brought into the ON state. Thereafter, the semiconductor device 20 repeatedly performs the ON state, the first turning-off, and the second turning-off.

According to the present embodiment, the semiconductor device 20 includes the emitter electrode 21, namely the first electrode, and the collector electrode 23 namely the second electrode, disposed with a gap left from each other in the first direction D1, the plurality of control electrodes 35 disposed between the emitter electrode 21 and the collector electrode 23 and disposed with gaps left in the second direction D2, the connection electrodes 43 electrically connected to the emitter electrode 21, the P-type base layers 29, that is, the first semiconductor layer of the P type, that is, the first conductivity type electrically connected to the emitter electrode 21, the P-type floating layers 30, namely the second semiconductor layers electrically insulated from the emitter electrode 21, the N⁻-type base layer 31, that is, the third semiconductor layer of the N type, that is, the second conductivity type, and the P-type collector layer 33, that is, the fourth semiconductor layer. Each of the P-type base layers 29, the P-type floating layers 30, the N⁻-type base layer 31, and the P-type collector layer 33 are disposed between the emitter electrode 21 and the collector electrode 23. Each of the plurality of regions sandwiched between the control electrodes 35 disposed to be adjacent to each other in the second direction D2 is either the channel region Rc where the P-type base layer 29 is disposed or the floating region Rf where the P-type floating layer 30 is disposed, the plurality of control electrodes 35 includes the plurality of first control electrodes 36 to which the first voltage Vg1 is applied and the plurality of second control electrodes 39 to which the second voltage Vg2 is applied, the floating region Rf includes the first floating region Rf1 where at least one of the control electrodes 35 sandwiching the floating region Rf is the second control electrode 39, and the connection electrodes 43 are disposed in the first floating regions Rf1.

As described above, it is possible to provide the second period of time P2 during which the second voltage Vg2 applied to the second control electrode 39 is switched to the second low voltage Lg2 and first turning-off is performed between the first period of time P1 during which the semiconductor device 20 is in the ON state and the third period of time P3 during which the semiconductor device 20 is in the OFF state in the present embodiment. Therefore, it is possible to discharge some of the holes accumulated in the N⁻-type base layer 31 to the emitter electrode 21 while causing the current to flow from the collector electrode 23 to the emitter electrode 21 in the second period of time P2. In this manner, it is possible to reduce the carrier concentration in the N⁻-type base layer 31 while curbing an excessive increase in resistance of the N⁻-type base layer 31 in the second period of time P2. Therefore, it is possible to reduce a turning-off loss in the third period of time P3.

However, in a case where the connection electrodes 43 are not included as in the semiconductor device 920 according to the aforementioned comparative example, the range of the hole discharge region Rd in the second direction D2 increases, and the carrier concentration in the N⁻-type base layer 31 excessively decreases in the second period of time P2. In this manner, the electrical resistance of the N⁻-type base layer 31 increases, a conductive loss in the second period of time P2 thus increases.

On the other hand, the connection electrodes 43 are disposed in the first floating region Rf1 as described above in the present embodiment. In this manner, it is possible to suitably reduce the range of the hole discharge region Rd in the second direction D2 and to thereby curb an excessive decrease in carrier concentration in the N⁻-type base layer 31 as described above. Therefore, it is possible to suitably curb an increase in conduction loss in the second period of time P2. Also, according to the present embodiment, it is possible to reduce the carrier concentration in the N⁻-type base layer 31 in the second period of time P2 and to thereby reduce the amount of holes discharged to the emitter electrode 21 in the third period of time P3 as described above. In this manner, it is possible to suitably shorten the time during which the carriers are discharged to the emitter electrode 21 in the third period of time P3. Therefore, it is possible to suitably reduce a turning-off loss in the third period of time P3. In other words, it is possible to suitably curb an increase in conduction loss in the second period of time P2 and to suitably reduce a turning-off loss in the third period of time P3 according to the semiconductor device 20 of the present embodiment.

Also, according to the present embodiment, it is possible to appropriately adjust the range of the hole discharge region Rd in the second direction D2 in the second period of time P2 by appropriately adjusting the position of each connection electrode 43 in the second direction D2. In this manner, it is possible to appropriately adjust the carrier concentration in the N⁻-type base layer 31 in the second period of time P2. Therefore, it is possible to more suitably curb an increase in conduction loss in the second period of time P2 and to more suitably reduce a turning-off loss in the third period of time P3.

Also, in the present embodiment, the connection electrodes 43 are electrically connected to the emitter electrode 21. Therefore, it is possible to stabilize the potential of the connection electrodes 43 at a potential near the emitter potential. In this manner, it is possible to stabilize a potential difference between the connection electrodes 43 and the collector electrode 23 and to thereby stabilize the amount of holes to be discharged to the emitter electrode 21 in the second period of time P2. Therefore, it is possible to more precisely adjust the carrier concentration in the N⁻-type base layer 31 in the second period of time P2. It is thus possible to more suitably curb an increase in conduction loss in the second period of time P2 and to more suitably reduce a turning-off loss in the third period of time P3.

According to the present embodiment, each first floating region Rf1 is sandwiched between one first control electrode 36 and one second control electrode 39, and the gap G2 between the connection electrodes 43 and the second control electrodes 39 is larger than the gap G1 between the connection electrodes 43 and the first control electrodes 36. Therefore, it is easy to increase the range of the hole discharge region Rd in the second direction D2 as described above. Therefore, it is possible to suitably increase the amount of carriers discharged to the emitter electrode 21 in the second period of time P2. Therefore, it is possible to suitably reduce the carrier concentration in the N-type base layer 31 and to thereby more suitably reduce a turning-off loss in the third period of time P3.

According to the present embodiment, each first floating region Rf1 is sandwiched between one first control electrode 36 and one second control electrode 39, and the gap G2 between the connection electrodes 43 and the second control electrodes 39 may be smaller than the gap G1 between the connection electrodes 43 and the first control electrodes 36. Therefore, it is easy to reduce the range of the hole discharge region Rd in the second direction D2 as described above. Therefore, it is possible to reduce the amount of carriers discharged to the emitter electrode 21 in the second period of time P2. Therefore, it is possible to curb an excessive decrease in carrier concentration in the N⁻-type base layer 31 and to thereby more suitably curb an increase in conduction loss in the second period of time P2.

According to the present embodiment, the semiconductor device 20 includes the voltage control circuit 50 capable of controlling the first voltage Vg1 and the second voltage Vg2 at mutually different timings. Therefore, it is possible to switch the second voltage Vg2 to be applied to the second control electrodes 39 to the second low voltage Lg2 while maintaining the first voltage Vg1 to be applied to the first control electrodes 36 at the first high voltage Hg1 at the clock time T2 as described above. In this manner, it is possible to discharge some of the holes to the emitter electrode 21 while causing a current to flow from the collector electrode 23 to the emitter electrode 21 in the second period of time P2 as described above. Therefore, it is possible to reduce the carrier concentration in the N⁻-type base layer 31 while curbing an excessive increase in resistance of the N⁻-type base layer 31 in the second period of time P2. Therefore, it is possible to suitably curb an increase in conduction loss in the second period of time P2 and to suitably reduce a turning-off loss in the third period of time P3.

According to the present embodiment, the voltage control circuit 50 switches the first voltage Vg1 after elapse of the predetermined time from switching of the second voltage Vg2. If the second period of time P2 is excessively short, the amount of carriers discharged to the emitter electrode 21 in the second period of time P2 decreases, and there is thus a concern that a turning-off loss in the third period of time P3 cannot sufficiently be reduced. Also, if the second period of time P2 is excessively long, there is a concern that an ON resistance may increase. To address these, the time of the second period of time P2 can be set to a desired time in the present embodiment. In this manner, it is possible to appropriately adjust the amount of carriers discharged to the emitter electrode 21 in the second period of time P2. Therefore, it is possible to more suitably curb an increase in conduction loss in the second period of time P2 and to more suitably reduce a turning-off loss in the third period of time P3.

According to the present embodiment, the voltage control circuit 50 switches the first voltage Vg1 and the second voltage Vg2 to the first high voltage Hg1 and the second high voltage Hg2, respectively, then switches the second voltage Vg2 to the second low voltage Lg2 which is a voltage lower than the second high voltage Hg2, and after elapse of a predetermined time from the switching of the second voltage Vg2 to the second low voltage Lg2, switches the first voltage Vg1 to the first low voltage Lg1 which is a voltage lower than the first high voltage Hg1. Therefore, it is possible to set the time of the second period of time P2 to a desired time in the present embodiment. In this manner, it is possible to appropriately adjust the amount of carriers discharged to the emitter electrode 21 in the second period of time P2. Therefore, it is possible to more suitably curb an increase in conduction loss in the second period of time P2 and to more suitably reduce a turning-off loss in the third period of time P3.

### Second Embodiment

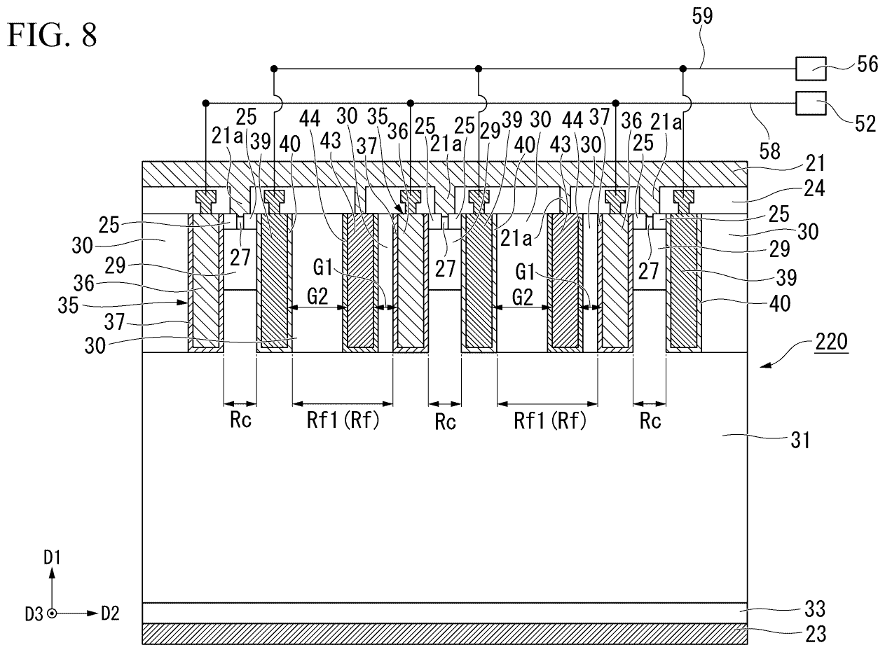

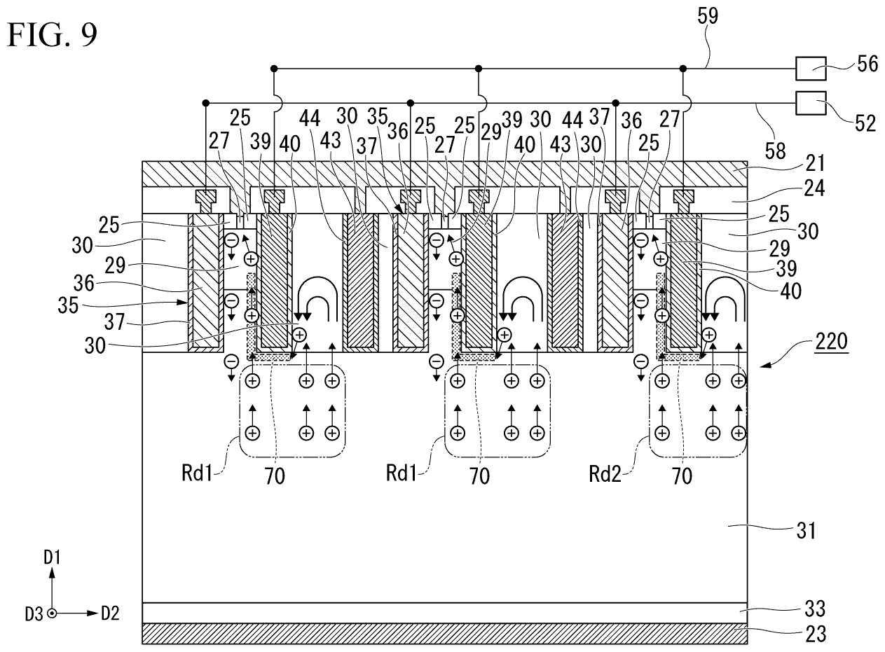

FIG. 8 is a schematic sectional view illustrating a semiconductor device 220 according to the present embodiment. FIG. 9 is a schematic sectional view illustrating a carrier behavior in a second period of time P2 of the semiconductor device 220 according to the present embodiment. First control electrodes 36 and second control electrodes 39 according to the present embodiment are alternately disposed along the second direction D2. Note that in the following description, components in the same aspects as those in the aforementioned first embodiment will be denoted by the same reference signs and a description thereof will be omitted.

As illustrated in FIG. 8, the plurality of control electrodes 35 includes the plurality of first control electrodes 36 and the plurality of second control electrodes 39 in the present embodiment. The first control electrodes 36 are disposed with gaps left along the second direction D2. The second control electrodes 39 are disposed with gaps left along the second direction D2. In the present embodiment, the second control electrodes 39 are disposed to be adjacent to the right side (+D2 side) of the mutually different first control electrodes 36. In other words, the first control electrodes 36 and the second control electrodes 39 are alternately disposed along the second direction D2 in the present embodiment.

In the present embodiment, channel regions Rc are regions between the first control electrodes 36 and the second control electrodes 39 disposed to be adjacent to the right side (+D2 side) of the first control electrodes 36. Each channel region Rc is sandwiched between the first control electrode 36 and the second control electrode 39. In the present embodiment, floating regions Rf are regions other than the channel regions Rc from among a plurality of regions sandwiched between the adjacent control electrodes 35 disposed to be adjacent to each other in the second direction D2. In the present embodiment, the floating regions Rf include first floating regions Rf1.

Each first floating region Rf1 is a region where at least one of the control electrodes 35 sandwiching the floating region Rf is the second control electrode 39. In the present embodiment, each first floating region Rf1 is sandwiched between one first control electrode 36 and one second control electrode 39. In the present embodiment, the channel regions Rc and the first floating regions Rf1 are alternately provided along the second direction D2. The other configurations of the semiconductor device 220 according to the present embodiment are similar to the other configurations of the semiconductor device 20 according to the aforementioned first embodiment.

In the present embodiment, the semiconductor device 220 experiences first turning-off at the clock time T2 similarly to the aforementioned first embodiment. In the present embodiment, a first control circuit 51 maintains a first voltage Vg1 at a first high voltage Hg1 at the clock time T2 similarly to the aforementioned first embodiment. A second control circuit 55 switches a second voltage Vg2 to a second low voltage Lg2. In this manner, a state where electrons move from an emitter electrode 21 to a collector electrode 23 via N⁺-type emitter layers 25 in contact with first insulating films 37 and P-type base layers 29 is maintained as illustrated in FIG. 9 at the clock time T2. In the present embodiment, the electrons move from the emitter electrode 21 to the collector electrode 23 through parts of the channel regions Rc on the side of the first control electrodes 36. In this manner, a state where a current flows from the collector electrode 23 to the emitter electrode 21 is also maintained.

Also, holes accumulated in the N⁻-type base layer 31 are discharged to the emitter electrode 21 via each channel region Rc. More specifically, holes accumulated in first hole discharge regions Rd1 which are regions obtained by adding parts of the N⁻-type base layer 31 overlapping the second control electrodes 39 when seen in the first direction D1 and parts of the first floating regions Rf1 overlapping the parts on the side further leftward (−D2 side) than the connection electrode 43 are discharged to the emitter electrode 21. In the present embodiment, the first hole discharge regions Rd1 are formed with a gap left along the second direction D2. Also, holes accumulated in a second hole discharge region Rd2 which is a region obtained by adding a part of the N⁻-type base layer 31 overlapping the second control electrode 39 disposed on the rightmost side (+D2 side) and a part overlapping the P-type floating layer 30 disposed on the side further rightward than that second control electrode 39 are discharged to the emitter electrode 21. Some of the holes accumulated in the first hole discharge regions Rd1 and the second hole discharge region Rd2 are discharged to the emitter electrode 21 via carrier accumulation layers 70, P-type base layers 29, and P⁺-type contact layers 27. Also, other holes accumulated in the first hole discharge regions Rd1 and the second hole discharge region Rd2 move to the P-type floating layers 30 and are then discharged to the emitter electrode 21 via the carrier accumulation layers 70, the P-type base layers 29, and the P⁺-type contact layers 27. In the present embodiment, the holes move to the emitter electrode 21 through parts of the channel regions Rc on the side of the second control electrodes 39.

In a second period of time P2, the semiconductor device 220 is in an ON state where a current flows from the collector electrode 23 to the emitter electrode 21 via each channel region Rc. Also, since some of the holes accumulated in the first hole discharge regions Rd1 and the second hole discharge region Rd2 are discharged to the emitter electrode 21 in the second period of time P2, it is possible to reduce the concentration of carriers accumulated in the N⁻-type base layer 31. In this manner, it is possible to reduce the carrier concentration in the N⁻-type base layer 31 while curbing an excessive increase in resistance of the N⁻-type base layer 31 in the second period of time P2 according to the present embodiment similarly to the aforementioned first embodiment. Therefore, it is possible to suitably curb an increase in conduction loss in the second period of time P2 and to suitably reduce a turning-off loss in a third period of time P3.

### Third Embodiment

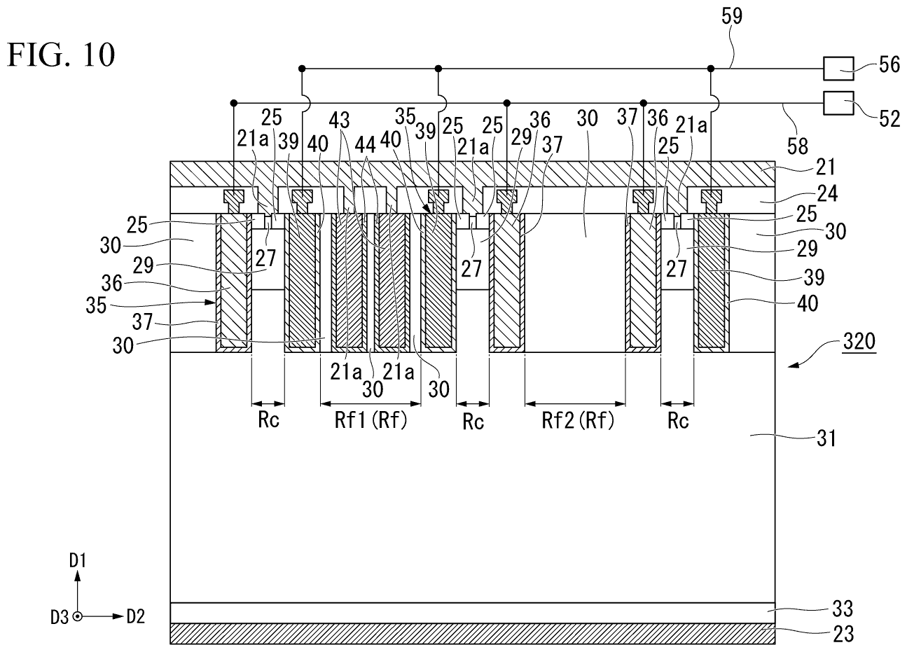

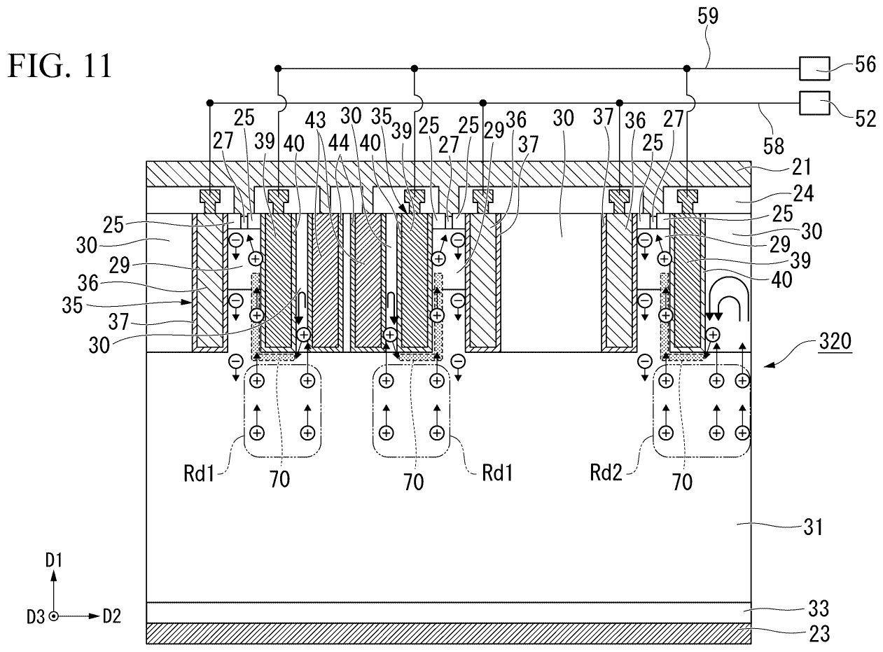

FIG. 10 is a schematic sectional view illustrating a semiconductor device 320 according to the present embodiment. FIG. 11 is a schematic sectional view illustrating a carrier behavior in a second period of time P2 of the semiconductor device 320 according to the present embodiment. A plurality of connection electrodes 43 are disposed in first floating region Rf1 according to the present embodiment. Note that in the following description, components in the same aspects as those in the aforementioned first embodiment will be denoted by the same reference signs and a description thereof will be omitted.

As illustrated in FIG. 10, the plurality of control electrodes 35 includes a plurality of first control electrodes 36 and a plurality of second control electrodes 39 in the present embodiment. The first control electrodes 36 are disposed with gaps left in the second direction D2. The second control electrodes 39 are disposed with gaps left in the second direction D2. In the present embodiment, the plurality of control electrodes 35 are disposed in order of one first control electrode 36, two second control electrodes 39, two first control electrodes 36, and one second control electrode 39 from the left side (−D2 side) to the right side (+D2 side).

In the present embodiment, channel regions Rc are regions sandwiched between the first control electrodes 36 and the second control electrodes 39. In the present embodiment, floating regions Rf are regions other than the channel regions Rc from among a plurality of regions sandwiched between the control electrodes 35 that are adjacent to each other in the second direction D2. In the present embodiment, the floating regions Rf include a first floating region Rf1 and a second floating region Rf2.

In the present embodiment, the first floating region Rf1 is a region sandwiched between two second control electrodes 39 in each floating region Rf. The second floating region Rf2 is a region sandwiched between two first control electrodes 36. In the present embodiment, each floating region Rf includes one first floating region Rf1 or one second floating region Rf2.

The semiconductor device 320 includes the plurality of connection electrodes 43. The connection electrodes 43 are disposed with gaps left from each other along the second direction D2. The connection electrodes 43 are disposed in the same first floating region Rf1. Therefore, the plurality of connection electrodes 43 disposed with gaps left from each other in the second direction D2 are disposed in the first floating region Rf1 in the present embodiment. In the present embodiment, two connection electrodes 43 are disposed in the first floating region Rf1. Three or more connection electrodes 43 may be disposed in the first floating region Rf1. Note that the connection electrode 43 is not disposed in the second floating region Rf2. The other configurations and the like of the semiconductor device 320 according to the present embodiment are similar to the other configurations and the like of the semiconductor device 20 according to the aforementioned first embodiment. Note that although the two connection electrodes 43 are disposed in the first floating region Rf1 in the present embodiment, one connection electrode with a dimension in the second direction D2 that is about double the dimension of each connection electrode 43 in the second direction D2 in the present embodiment may be disposed.

In the present embodiment, the semiconductor device 320 experiences first turning-off at a clock time T2 similarly to the aforementioned first embodiment. In the present embodiment, a first control circuit 51 maintains a first voltage Vg1 at a first high voltage Hg1 at the clock time T2 similarly to the aforementioned first embodiment. A second control circuit 55 switches a second voltage Vg2 to a second low voltage Lg2. In this manner, a state where electrons move from an emitter electrode 21 to a collector electrode 23 via N⁺-type emitter layers 25 in contact with the first insulating films 37 and P-type base layers 29 is maintained as illustrated in FIG. 11 at the clock time T2. In the present embodiment, electrons move from the emitter electrode 21 to the collector electrode 23 through parts of the channel regions Rc on the side of the first control electrodes 36. In this manner, a state where a current flows from the collector electrode 23 to the emitter electrode 21 via each channel region Rc is also maintained.

Also, holes accumulated in the N⁻-type base layer 31 are discharged to the emitter electrode 21 via each channel region Rc. More specifically, holes accumulated in first hole discharge regions Rd1 which are regions obtained by adding parts of the N⁻-type base layer 31 overlapping the second control electrodes 39 when seen in the first direction D1 and a part of the first floating region Rf1 overlapping parts between the connection electrodes 43 and the second control electrodes 39 are discharged to the emitter electrode 21. In the present embodiment, the first hole discharge regions Rd1 are formed with a gap left in the second direction D2. Also, holes accumulated in a second hole discharge region Rd2 which is a region obtained by adding a part of the N⁻-type base layer 31 overlapping the second control electrode 39 disposed on the rightmost side (+D2 side) when seen in the first direction D1 and a part of the N⁻-type base layer 31 overlapping the P-type floating layer 30 disposed on the side further rightward than that second control electrode 39 are discharged to the emitter electrode 21. Some of the holes accumulated in the first hole discharge regions Rd1 and the second hole discharge region Rd2 are discharged to the emitter electrode 21 via the carrier accumulation layers 70, the P-type base layers 29, and the P⁺-type contact layers 27. Also, other holes accumulated in the first hole discharge region Rd1 and the second hole discharge region Rd2 move to the P-type floating layers 30 and are then discharged to the emitter electrode 21 via the carrier accumulation layers 70, the P-type base layers 29, and the P⁺-type contact layers 27. In the present embodiment, the holes move to the emitter electrode 21 through parts of the channel regions Rc on the side of the second control electrodes 39.

In the second period of time P2, the semiconductor device 320 is in an ON state where a current flows from the collector electrode 23 to the emitter electrode 21 via each channel region Rc. Also, since some of the holes accumulated in the first hole discharge regions Rd1 and the second hole discharge region Rd2 are discharged to the emitter electrode 21 in the second period of time P2, it is possible to reduce the concentration of carriers accumulated in the N⁻-type base layer 31. In this manner, it is possible to reduce the carrier concentration in the N⁻-type base layer 31 while curbing an excessive increase in resistance of the N⁻-type base layer 31 in the second period P2 according to the present embodiment similarly to the first embodiment. Therefore, it is possible to suitably curb an increase in conduction loss in the second period of time P2 and to suitably reduce a turning-off loss in the third period of time P3.

According to the present embodiment, the first floating region Rf1 is sandwiched between the two second control electrodes 39, and the plurality of connection electrodes 43 disposed with a gap left from each other along the second direction D2 are disposed in the first floating region Rf1. Since the P-type floating layers 30 have conductivity, the carriers accumulated in the part of the N⁻-type base layer 31 overlapping the first floating region Rf1 when seen in the first direction D1 are discharged to the emitter electrode 21 in a case where the number of connection electrodes 43 disposed in the first floating region Rf1 is one. Therefore, there is a concern that the amount of carriers discharged from the N⁻-type base layer 31 may become excessively large in the second period of time P2.

On the other hand, according to the present embodiment, the plurality of connection electrodes 43 are disposed in the first floating region Rf1, and carriers are unlikely to be discharged from each of the part of the N⁻-type base layer 31 overlapping the plurality of connection electrodes 43 when seen in the first direction D1 and the parts of the N⁻-type base layer 31 between the plurality of connection electrodes 43 to the emitter electrode 21. It is thus possible to curb an excessive increase in the amount of carriers discharged from the N⁻-type base layer 31 to the emitter electrode 21 in the second period of time P2. Therefore, it is possible to curb an excessive decrease in the carrier concentration in the N⁻-type base layer 31 in the second period of time P2 and to thereby more suitably curb an increase in conduction loss in the second period of time P2.

According to at least one of the embodiments described above, it is possible to provide a semiconductor device capable of reducing both a conduction loss and a turning-off loss by disposing the connection electrodes in the first floating region.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first electrode and a second electrode disposed with a gap left from each other in a first direction;
a plurality of control electrodes disposed between the first electrode and the second electrode and disposed with gaps left in a second direction that intersects the first direction;
connection electrodes electrically connected to the first electrode;
a first semiconductor layer of a first conductivity type electrically connected to the first electrode;
a second semiconductor layer of the first conductivity type electrically insulated from the first electrode;
a third semiconductor layer of a second conductivity type disposed between the second electrode and each of the first semiconductor layer and the second semiconductor layer; and
a fourth semiconductor layer of the first conductivity type disposed between the second electrode and the third semiconductor layer,
wherein each of the first semiconductor layer, the second semiconductor layer, the third semiconductor layer, and the fourth semiconductor layer is disposed between the first electrode and the second electrode,
each of a plurality of regions sandwiched between the control electrodes disposed to be adjacent to each other in the second direction is either a channel region where the first semiconductor layer is disposed or a floating region where the second semiconductor layer is disposed,
the plurality of control electrodes includes a plurality of first control electrodes to which a first voltage is applied and a plurality of second control electrodes to which a second voltage is applied,
the floating region includes a first floating region where at least one of the control electrodes sandwiching the floating region is the second control electrode, and
the connection electrodes are disposed in the first floating region.

2. The semiconductor device according to claim 1,
wherein the first floating region is sandwiched between one of the first control electrodes and one of the second control electrodes, and
a gap between the connection electrodes and the second control electrodes is larger than a gap between the connection electrodes and the first control electrodes.

3. The semiconductor device according to claim 1,
wherein the first floating region is sandwiched between one of the first control electrodes and one of the second control electrodes, and
a gap between the connection electrodes and the second control electrodes is smaller than a gap between the connection electrodes and the first control electrodes.

4. The semiconductor device according to claim 1,
wherein the first floating region is sandwiched by two of the second control electrodes, and
the plurality of connection electrodes disposed with gaps left from each other along the second direction are disposed in the first floating region.

5. The semiconductor device according to claim 1, further comprising:
a voltage control circuit that is configured to control the first voltage and the second voltage at mutually different timings.

6. The semiconductor device according to claim 5, wherein the voltage control circuit switches the first voltage after elapse of a predetermined time from switching of the second voltage.

7. The semiconductor device according to claim 5, wherein the voltage control circuit switches the first voltage and the second voltage to a first high voltage and a second high voltage, respectively, then switches the second voltage to a second low voltage that is a voltage lower than the second high voltage, and after elapse of a predetermined time after switching the second voltage to the second low voltage, switches the first voltage to a first low voltage that is a voltage lower than the first high voltage.
